(19) United States
(12) Patent Application Publication
(10) Pub. No.: US 2025/0377392 A1
(43) Pub. Date: Dec. 11, 2025

(54) Capacitance Detection Method, Chip, and Electronic Device

(71) Applicant: SHANGHAI AWINIC MICROELECTRONICS TECHNOLOGY CO., LTD., Shanghai (CN)

(72) Inventors: Zhou XU, Shanghai (CN); Mingda CHEN, Shanghai (CN); Zhong ZHANG, Shanghai (CN)

(73) Assignee: SHANGHAI AWINIC MICROELECTRONICS TECHNOLOGY CO., LTD., Shanghai (CN)

(21) Appl. No.: 18/753,620

(22) Filed: Jun. 25, 2024

Related U.S. Application Data
(63) Continuation of application No. PCT/CN2024/098266, filed on Jun. 7, 2024.

(51) Int. Cl. G01R 27/26; G06F 3/044

(52) U.S. Cl. CPC G01R 27/2605; G06F 3/044

(57) ABSTRACT

This disclosure relates to the field of capacitance detection technologies, and discloses a capacitance detection method, chip, and electronic device. The method includes: determining a capacitance variation corresponding to the n th capacitance sampling data, based on temperature compensation data corresponding to the n th capacitance sampling data and a baseline value corresponding to the (n−1) th capacitance sampling data; determining a state of a human body relative to an electronic device based on size relationship between the capacitance variation and a proximity threshold; determining a trend variation corresponding to the n th capacitance sampling data based on temperature compensation data corresponding to the first n capacitance sampling data; determining a baseline value corresponding to the n th capacitance sampling data based on the size relationship, and the trend variation. In the method, accuracy of determining the state of the human body relative to the electronic device can be improved.

### CROSS-REFERENCE TO RELATED APPLICATIONS

This application is a continuation of international application No. PCT/CN2024/098266 filed on Jun. 7, 2024.

### TECHNICAL FIELD

This disclosure relates to the field of capacitance detection technologies, and in particular, to a capacitance detection method, chip, and electronic device.

### BACKGROUND

Currently, capacitance sensors are widely used in electronic devices such as mobile phones and earphones. A change in capacitance detected by a capacitance sensor may be used to identify whether a human body or a conductor is close to an electronic device (e.g., a mobile phone). However, because a change in environment temperature may also cause change of the capacitance detected by the capacitance sensor, the state of a human body for approaching or leaving the electronic device may be misjudged.

### SUMMARY

Based on above description, embodiments of this disclosure provide a capacitance detection method, chip, and electronic device, so as to resolve a problem in misjudging whether a human body is approaching or leaving an electronic device.

In a first aspect, a capacitance detection method is provided. The method comprising: determining a capacitance variation corresponding to the n th capacitance sampling data, based on temperature compensation data corresponding to the n th capacitance sampling data of a to-be-detected capacitor and a baseline value corresponding to the (n−1) th capacitance sampling data of the to-be-detected capacitor when n is a positive integer greater than or equal to 2; and the capacitance variation corresponding to the n th capacitance sampling data is 0 when n equals 1; determining a state of a human body relative to an electronic device based on size relationship between the capacitance variation corresponding to the n th capacitance sampling data and a proximity threshold; determining a trend variation corresponding to the n th capacitance sampling data based on temperature compensation data corresponding to the first n capacitance sampling data; determining a baseline value corresponding to the n th capacitance sampling data based on the size relationship between the capacitance variation corresponding to the n th capacitance sampling data and the proximity threshold, as well as the trend variation corresponding to the n th capacitance sampling data.

In this method, the capacitance variation is determined based on the temperature compensation data obtained by performing temperature compensation on the current capacitance sampling data and the baseline value corresponding to the last capacitance sampling data, instead of the original capacitance sampling data, which can effectively overcome an impact of environment temperature, improving accuracy of determining a state of a human body relative to an electronic device.

In addition, the trend variation corresponding to the current capacitance sampling data are determined based on temperature compensation data corresponding to all historical capacitance sampling data. Compared with some solutions in which the trend variation is determined by adopting the current capacitance sampling data, the last capacitance sampling data, and the capacitance sampling data in a limited time window, in this disclosure, long-term variation information of the capacitance can be reflected. Therefore, the accuracy of determining a state of a human body relative to an electronic device can be further improved.

In one or more possible implementations of the first aspect, determining a trend variation corresponding to the n th capacitance sampling data based on temperature compensation data corresponding to the first n capacitance sampling data comprises: determining the trend variation corresponding to the n th capacitance sampling data based on the following formula:

$$delta [ n ] = \{ \begin{matrix}( 1 - detcoef ) * delta [ n - 1 ] + detcoef * ( comp [ n ] - comp [ n - 1 ] ) , & n \geq 2 \\ 0 , & n = 1\end{matrix}$$

wherein delta[n] is the trend variation corresponding to the n th capacitance sampling data; delta[n−1] is trend variation corresponding to the (n−1) th capacitance sampling data; comp[n] is the temperature compensation data corresponding to the n th capacitance sampling data; comp[n−1] is temperature compensation data corresponding to the (n−1) th capacitance sampling data; detcoef is a first adjustment coefficient, and 0<detcoef<1.

In one or more possible implementations of the first aspect, determining a baseline value corresponding to the n th capacitance sampling data based on the size relationship between the capacitance variation corresponding to the n th capacitance sampling data and the proximity threshold, as well as the trend variation corresponding to the n th capacitance sampling data comprises:

taking the baseline value corresponding to the (n−1) th capacitance sampling data as the baseline value corresponding to the n th capacitance sampling data, when the capacitance variation corresponding to the n th capacitance sampling data is less than the proximity threshold and multiple trend variations corresponding to consecutive y times of capacitance sampling data are all greater than a first threshold; determining the baseline value corresponding to the n th capacitance sampling data based on the baseline value corresponding to the (n−1) th capacitance sampling data and the temperature compensation data corresponding to the n th capacitance sampling data, when the capacitance variation corresponding to the n th capacitance sampling data is less than the proximity threshold and the multiple trend variations corresponding to consecutive y times of capacitance sampling data are not all greater than the first threshold; wherein y is a positive integer greater than or equal to 1.

In one or more possible implementations of the first aspect, determining the baseline value corresponding to the n th capacitance sampling data based on the baseline value corresponding to the (n−1) th capacitance sampling data and the temperature compensation data corresponding to the n th capacitance sampling data comprises: determining the baseline value corresponding to the n th capacitance sampling data based on the following formula:

$$basic [ n ] = basic [ n - 1 ] + basiccoef * ( comp [ n ] - basic [ n - 1 ] )$$

wherein basic[n] is the baseline value corresponding to the n th capacitance sampling data; basic[n−1] is the baseline value corresponding to the (n−1) th capacitance sampling data; comp[n] is the temperature compensation data corresponding to the n th capacitance sampling data; basiccoef is a second adjustment coefficient, and 0≤basiccoef≤1.

In one or more possible implementations of the first aspect, determining a baseline value corresponding to the n th capacitance sampling data based on the size relationship between the capacitance variation corresponding to the n th capacitance sampling data and the proximity threshold, as well as the trend variation corresponding to the n th capacitance sampling data further comprises: taking the baseline value corresponding to the (n−1) th capacitance sampling data as the baseline value corresponding to the n th capacitance sampling data, when the capacitance variation corresponding to the n th capacitance sampling data is greater than or equal to the proximity threshold; and the trend variation corresponding to the n th capacitance sampling data is greater than or equal to a second threshold, and less than or equal to a third threshold, or the trend variation corresponding to the n th capacitance sampling data are greater than or equal to a fourth threshold, and less than or equal to a fifth threshold, wherein the third threshold is less than the fourth threshold.

In one or more possible implementations of the first aspect, determining a baseline value corresponding to the n th capacitance sampling data based on the size relationship between the capacitance variation corresponding to the n th capacitance sampling data and the proximity threshold, as well as the trend variation corresponding to the n th capacitance sampling data further comprises: performing a first correction processing on the baseline value corresponding to the (n−1) th capacitance sampling data to obtain the baseline value corresponding to the n th capacitance sampling data, when the capacitance variation corresponding to the n th capacitance sampling data is greater than or equal to the proximity threshold and the trend variation corresponding to the n th capacitance sampling data is greater than the fifth threshold; performing a second correction processing on the baseline value corresponding to the (n−1) th capacitance sampling data to obtain the baseline value corresponding to the n th capacitance sampling data, when the capacitance variation corresponding to the n th capacitance sampling data is greater than or equal to the proximity threshold and the trend variation corresponding to the n th capacitance sampling data is less than the second threshold.

In one or more possible implementations of the first aspect, performing a first correction processing on the baseline value corresponding to the (n−1) th capacitance sampling data to obtain the baseline value corresponding to the n th capacitance sampling data comprises: obtaining the baseline value corresponding to the n th capacitance sampling data based on the following formula:

$$basic [ n ] = basic [ n - 1 ] + limitcoef * limit 1$$

wherein basic[n] is the baseline value corresponding to the n th capacitance sampling data; basic[n−1] is the baseline value corresponding to the n th capacitance sampling data; limitcoef is a third adjustment coefficient; limit1 is a first preset parameter; and 0≤limitcoef≤1, −32768≤limit1≤32768;

performing a second correction processing on the baseline value corresponding to the (n−1) th capacitance sampling data to obtain the baseline value corresponding to the n th capacitance sampling data comprises: obtaining the baseline value corresponding to the n th capacitance sampling data based on the following formula:

$$basic [ n ] = basic [ n - 1 ] + limitcoef * limit 2$$

wherein basic[n] is the baseline value corresponding to the n th capacitance sampling data; basic[n−1] is the baseline value corresponding to the n th capacitance sampling data; limitcoef is the third adjustment coefficient; limit2 is a second preset parameter; and 0≤limitcoef≤1, −32768≤limit2≤32768.

In one or more possible implementations of the first aspect, determining a baseline value corresponding to the n th capacitance sampling data based on the size relationship between the capacitance variation corresponding to the n th capacitance sampling data and the proximity threshold, as well as the trend variation corresponding to the n th capacitance sampling data further comprises: determining the baseline value corresponding to the n th capacitance sampling data based on the baseline value corresponding to the (n−1) th capacitance sampling data and the trend variation corresponding to the n th capacitance sampling data, when the capacitance variation corresponding to the n th capacitance sampling data is greater than or equal to the proximity threshold; and the trend variation corresponding to the n th capacitance sampling data is greater than the third threshold and less than the fourth threshold.

In one or more possible implementations of the first aspect, determining the baseline value corresponding to the n th capacitance sampling data based on the baseline value corresponding to the (n−1) th capacitance sampling data and the trend variation corresponding to the n th capacitance sampling data comprises: obtaining the baseline value corresponding to the n th capacitance sampling data based on the following formula:

$$basic [ n ] = basic [ n - 1 ] + coef * delta [ n ]$$

wherein basic[n] is the baseline value corresponding to the n th capacitance sampling data; basic[n−1] is the baseline value corresponding to the n th capacitance sampling data; coef is a fourth adjustment coefficient, and 0≤coef≤1.

In a second aspect, a chip is provided. The chip is configured to execute the capacitance detection method in the first aspect mentioned above.

In a third aspect, an electronic device is provided. The electronic device comprises the chip mentioned in the second aspect above.

### BRIEF DESCRIPTION OF THE DRAWINGS

FIG. 1 is a schematic flow diagram of a capacitance detection method according to some embodiments of this disclosure.

FIG. 2 is a schematic flow diagram of a detailed capacitance detection method according to some embodiments of this disclosure.

### DETAILED DESCRIPTION

Illustrative embodiments of this disclosure include but are not limited to a capacitance detection method, chip, and electronic device.

The electronic device in embodiments of this disclosure may include but is not limited to any device with capacitance sensors, such as a mobile phone, a tablet computer, a notebook computer, a camera, a super mobile personal computer, a handheld computer, a television, an intercom, a netbook, a POS machine, a personal digital assistant (PDA), a wearable device, a virtual reality device, an intelligent vehicle, and an intelligent robot.

To resolve the foregoing problem, embodiments of this disclosure provide a capacitance detection method, and the method includes: determining a capacitance variation corresponding to the n th capacitance sampling data, based on temperature compensation data corresponding to the n th capacitance sampling data and a baseline value corresponding to the (n−1) th capacitance sampling data of a to-be-detected capacitor. The baseline value corresponding to the (n−1) th capacitance sampling data is determined based on a trend variation corresponding to the first (n−1) capacitance sampling data. The trend variation corresponding to the (n−1) th capacitance sampling data is determined based on temperature compensation data corresponding to the first (n−1) capacitance sampling data, and n is a positive integer greater than or equal to 2. Determining a state of a human body relative to the electronic device based on the capacitance variation corresponding to the n th capacitance sampling data and a proximity threshold.

In embodiments of this disclosure, the capacitance variation is determined based on the temperature compensation data obtained by performing temperature compensation on the current capacitance sampling data and the baseline value corresponding to the last capacitance sampling data, instead of the original capacitance sampling data, which can effectively overcome an impact of environment temperature, improving accuracy of determining a state of a human body relative to an electronic device.

In addition, the trend variation corresponding to the current capacitance sampling data are determined based on temperature compensation data corresponding to all historical capacitance sampling data. Compared with some solutions in which the trend variation is determined by adopting the current capacitance sampling data, the last capacitance sampling data, and the capacitance sampling data in a limited time window, in this disclosure, long-term variation information of the capacitance can be reflected. Therefore, the accuracy of determining a state of a human body relative to an electronic device can be further improved.

The following describes in detail a capacitance detection method provided in this disclosure.

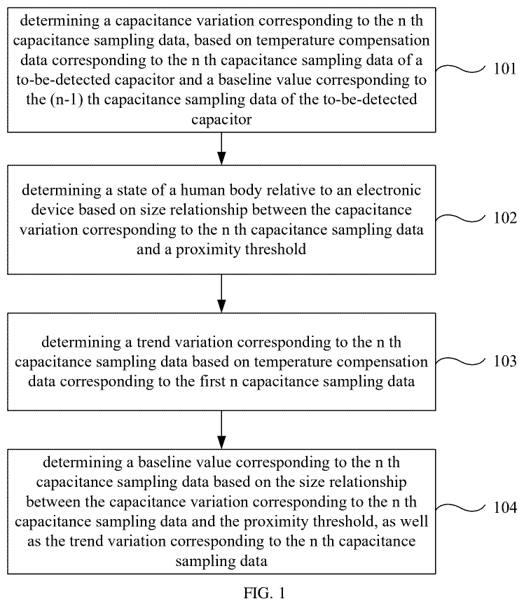

FIG. 1 shows a schematic flow diagram of a capacitance detection method. As shown in FIG. 1, the capacitance detection method may include the following steps:

101: determining a capacitance variation corresponding to the n th capacitance sampling data, based on temperature compensation data corresponding to the n th capacitance sampling data of a to-be-detected capacitor and a baseline value corresponding to the (n−1) th capacitance sampling data of the to-be-detected capacitor.

When n is a positive integer greater than or equal to 2, the capacitance variation corresponding to the n th capacitance sampling data can be determined based on a difference between the temperature compensation data corresponding to the n th capacitance sampling data and the baseline value corresponding to the (n−1) th capacitance sampling data of the to-be-detected capacitor. When n is equal to 1, the capacitance variation corresponding to the n th capacitance sampling data is 0.

For example, see the formula 1 below:

$$cap [ n ] = \{ \begin{matrix}comp [ n ] - basic [ n - 1 ] , & n \geq 2 \\ 0 , & n = 1\end{matrix} \qquad i . Formula 1$$

In the formula 1, cap[n] is the capacitance variation corresponding to the n th capacitance sampling data; comp[n] is the temperature compensation data corresponding to the n th capacitance sampling data; basic[n−1] is the baseline value corresponding to the (n−1) th capacitance sampling data.

In some embodiments, the capacitance sampling data may be compensated based on a temperature compensation coefficient, so as to obtain temperature compensation data. For example, temperature difference data may be multiplied by a fixed temperature compensation coefficient to obtain a product, which may be used as a capacitance compensation value. And the capacitance compensation value is subtracted from the capacitance sampling data to obtain the temperature compensation data. The temperature difference data may be a difference between the current temperature data and preset temperature data. It may be understood that the foregoing manner of obtaining the temperature compensation data is merely an example, and any temperature compensation manner may be applied, which is not limited in this disclosure.

102: determining a state of a human body relative to an electronic device based on size relationship between the capacitance variation corresponding to the n th capacitance sampling data and a proximity threshold (e.g., Prox).

In some embodiments, when the capacitance variation corresponding to the n th capacitance sampling data is less than the proximity threshold, it is determined that the human body is leaving the electronic device.

In some embodiments, when the capacitance variation corresponding to the n th capacitance sampling data is greater than or equal to the proximity threshold, it is determined that the human body is approaching the electronic device.

103: determining a trend variation corresponding to the n th capacitance sampling data based on temperature compensation data corresponding to the first n capacitance sampling data.

In some embodiments, the way of determining trend variation corresponding to the n th capacitance sampling data may be shown in formula 2:

$$delta [ n ] = \{ \begin{matrix}( 1 - det coef ) * delta [ n - 1 ] + det coef * & n \geq 2 \\ ( comp [ n ] - comp [ n - 1 ] ) , & \\ 0 , & n = 1\end{matrix} \qquad i . Formula 2$$

In formula 2, delta[n] is trend variation corresponding to the n th capacitance sampling data; delta[n−1] is trend variation corresponding to the (n−1) th capacitance sampling data; comp[n] is the temperature compensation data corresponding to the n th capacitance sampling data; comp[n−1] is the temperature compensation data corresponding to the (n−1) th capacitance sampling data; detcoef is a first adjustment coefficient, and 0<detcoef<1.

Based on the foregoing formula 2, a formula for calculating the trend variation corresponding to the second capacitance sampling data may be obtained (e.g. formula 3).

$$delta [ 2 ] = ( 1 - det coef ) * delta [ 1 ] + det coef * ( comp [ 2 ] - comp [ 1 ] ) \qquad Formula 3$$

In the formula 3, delta[2] is the trend variation corresponding to the second capacitance sampling data; delta[1] is the trend variation corresponding to the first capacitance sampling data; comp[2] is the temperature compensation data corresponding to the second capacitance sampling data; comp[1] is the temperature compensation data corresponding to the first capacitance sampling data.

The formula 3 may indicate that the trend variation corresponding to the second capacitance sampling data is related to the temperature compensation data corresponding to the first capacitance sampling data and the second capacitance sampling data.

Calculation way of the trend variation corresponding to the third capacitance sampling data is shown in formula 4:

$$delta [ 3 ] = ( 1 - det coef ) * delta [ 2 ] + det coef * ( comp [ 3 ] - comp [ 2 ] ) = ( 1 - det coef ) * ( 1 - det coef ) * delta [ 1 ] + det coef * ( 1 - det coef ) * ( comp [ 2 ] - comp [ 1 ] ) + det coef * ( comp [ 3 ] - comp [ 2 ] ) \qquad formula 4$$

In the formula 4, delta[3] is trend variation corresponding to the third capacitance sampling data, and comp[3] is temperature compensation data corresponding to the third capacitance sampling data.

The formula 4 may indicate that the trend variation corresponding to the third capacitance sampling data is related to the temperature compensation data corresponding to the first capacitance sampling data, the second capacitance sampling data, and the third capacitance sampling data.

Calculation way of the trend variation corresponding to the (n−1) th capacitance sampling data is shown in formula 5:

$$delta [ n - 1 ] = ( 1 - det coef ) * delta [ n - 2 ] + det coef * ( comp [ n - 1 ] - comp [ n - 2 ] ) \qquad Formula 5$$

In the formula 5, delta[n−1] is trend variation corresponding to the (n−1) th capacitance sampling data.

In summary, by analogy, the trend variation corresponding to the n th capacitance sampling data are related to temperature compensation data corresponding to the 1, 2, . . . , n th capacitance sampling data. In this way, the trend variation can reflect the long-term variation information of the capacitance, further improving accuracy of determining the state of the human body relative to the electronic device.

In some embodiments, the value of detcoef is determined based on variation of the temperature compensation data corresponding to the n th capacitance sampling data relative to the temperature compensation data corresponding to the first (n−1) capacitance sampling data. The variation of the temperature compensation data corresponding to the n th capacitance sampling data relative to the temperature compensation data corresponding to the first (n−1) capacitance sampling data may reflect a jitter situation of the temperature compensation data corresponding to the n th capacitance sampling data.

For example, a first difference between the temperature compensation data corresponding to the n th capacitance sampling data and the temperature compensation data corresponding to the (n−1) th capacitance sampling data may be obtained. If an absolute value of the first difference is greater than a first preset value, it is determined that the jitter is strong. If the absolute value of the first difference is less than the first preset value, it is considered that the jitter is weak.

In some embodiments, a second difference between the temperature compensation data corresponding to the n th capacitance sampling data and the temperature compensation data corresponding to the (n−1) th capacitance sampling data may be obtained. If an absolute value of the second difference is greater than a second preset value, it is determined that the jitter is strong. If the absolute value of the second difference is less than the second preset value, it is considered that the jitter is weak. The second preset value is greater than the first preset value.

If the jitter of the temperature compensation data corresponding to the n th capacitance sampling data is relatively strong, the value of detcoef may be appropriately reduced, so as to reduce trend variation. If the jitter of the temperature compensation data corresponding to the n th capacitance sampling data is relatively weak, the value of detcoef may be appropriately increased, so as to increase trend variation. In this way, more accurate trend variation can be obtained, thereby further improving accuracy of determining the state of the human body relative to the electronic device.

104: determining a baseline value corresponding to the n th capacitance sampling data based on the size relationship between the capacitance variation corresponding to the n th capacitance sampling data and the proximity threshold, as well as the trend variation corresponding to the n th capacitance sampling data.

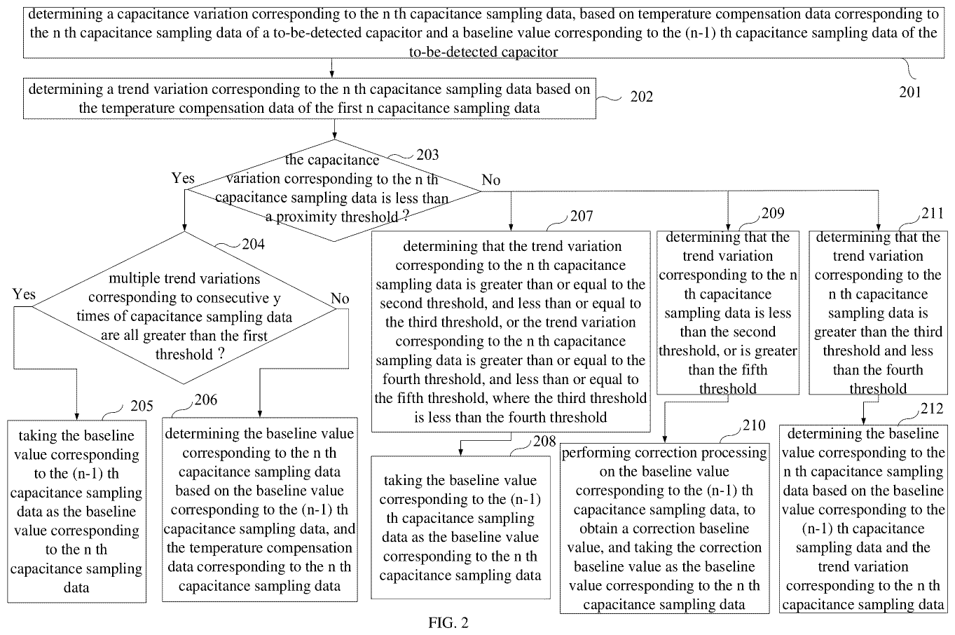

The way of determining the baseline value corresponding to the n th capacitance sampling data based on size relationship between the capacitance variation corresponding to the n th capacitance sampling data and the proximity threshold, as well as the trend capacitance variation corresponding to the n th capacitance sampling data may be referred to steps 204-212 in FIG. 2.

FIG. 2 shows a schematic flow diagram of a detailed capacitance detection method according to this disclosure. As shown in FIG. 2, the method includes the following steps.

201: determining a capacitance variation corresponding to the n th capacitance sampling data, based on temperature compensation data corresponding to the n th capacitance sampling data of a to-be-detected capacitor and a baseline value corresponding to the (n−1) th capacitance sampling data of the to-be-detected capacitor.

The principle of step 201 is similar to that of step 101, and details will not be described herein again.

202: determining a trend variation corresponding to the n th capacitance sampling data based on the temperature compensation data of the first n capacitance sampling data.

The principle of step 202 is similar to step 103, and details will not be described herein again.

203: whether the capacitance variation corresponding to the n th capacitance sampling data is less than a proximity threshold.

If so, step 204 may be conducted, which aims to determine whether multiple trend variations corresponding to consecutive y times of capacitance sampling data are all greater than the first threshold. If not, steps 207, 209, 211 may be conducted.

In some embodiments, it may be determined whether the capacitance variation corresponding to the n th capacitance sampling data is less than the proximity threshold. If so, it indicates that the human body corresponding to the current n th capacitance sampling data is leaving the electronic device, and steps 204-206 are conducted. If the capacitance variation corresponding to the n th capacitance sampling data is greater than or equal to the proximity threshold, it indicates that the human body is approaching the electronic device, and steps 207-212 are conducted.

204: whether multiple trend variations corresponding to consecutive y times of capacitance sampling data are all greater than the first threshold (e.g. th0), where y is a positive integer greater than or equal to 1.

If so, step 205 may be conducted. In step 205, the baseline value corresponding to the (n−1) th capacitance sampling data may be taken as the baseline value corresponding to the n th capacitance sampling data. If not, step 206 may be conducted. In step 206, the baseline value corresponding to the n th capacitance sampling data may be determined based on the baseline value corresponding to the (n−1) th capacitance sampling data, and the temperature compensation data corresponding to the n th capacitance sampling data.

In some embodiments, after determining that the capacitance variation corresponding to the n th capacitance sampling data is less than the proximity threshold, whether multiple trend variations corresponding to consecutive y times of capacitance sampling data are all greater than the first threshold can be determined then, where y is a positive integer greater than or equal to 1. For example, y can be 1, or any positive integer greater than or equal to 2. The value of y can be set according to actual requirements, which is not limited herein.

In this disclosure, when y is a positive integer greater than or equal to 2, by determining whether multiple trend variations corresponding to consecutive several times of capacitance sampling data are all greater than the first threshold, accuracy of determining the state of the human body relative to the electronic device may be improved.

For the n th capacitance sampling data, multiple trend variations corresponding to consecutive y times of capacitance sampling data are all greater than the first threshold may mean that multiple trend variations from the trend variation corresponding to the (n−y+1) th capacitance sampling data to the trend variation corresponding to the n th capacitance sampling data are all greater than the first threshold.

When the multiple trend variations corresponding to consecutive y times of capacitance sampling data are greater than the first threshold, it is considered that the human body is approaching the electronic device. In this case, the baseline may be set to be in a frozen state. That is to say, the baseline value corresponding to the (n−1) th capacitance sampling data is used as the baseline value corresponding to the n th capacitance sampling data. By doing so, the situation where an approaching state cannot be triggered due to incorrect tracing of baseline value may be prevented. That is to say, the situation where the electronic device cannot accurately recognize that the human body is approaching may be prevented. Therefore, the accuracy of determining the state of the human body relative to the electronic device may be improved.

If the multiple trend variation corresponding to the consecutive y times of capacitance sampling data are not all greater than the first threshold, it may be determined that the trend variation being greater than the first threshold is caused by external noise. In this case, the baseline value corresponding to the n th capacitance sampling data may be determined based on the baseline value corresponding to the (n−1) th capacitance sampling data, and the temperature compensation data corresponding to the n th capacitance sampling data. By doing so, the situation of incorrect tracing of baseline value caused by the noise may be effectively prevented.

In some embodiments, the multiple trend variations corresponding to the consecutive y times of capacitance sampling data are not all greater than the first threshold may be: at least one trend variation in the multiple trend variations corresponding to the (n−y+1) th capacitance sampling data to the n th capacitance sampling data is less than or equal to the first threshold. For example, the multiple trend variations corresponding to the (n−y+1) th capacitance sampling data to the n th capacitance sampling data are all less than or equal to the first threshold, or one or more trend variations (not all trend variations) corresponding to the (n−y+1) th capacitance sampling data to the n th capacitance sampling data are less than or equal to the first threshold.

When y is 1, the electronic device responds most quickly to the capacitance detection. The greater y is, the stronger the anti-noise capability to the capacitance detection of the electronic device is.

205: taking the baseline value corresponding to the (n−1) th capacitance sampling data as the baseline value corresponding to the n th capacitance sampling data.

In this disclosure, taking the baseline value corresponding to the (n−1) th capacitance sampling data as the baseline value corresponding to the n th capacitance sampling data is making the baseline be in a frozen state.

206: determining the baseline value corresponding to the n th capacitance sampling data based on the baseline value corresponding to the (n−1) th capacitance sampling data, and the temperature compensation data corresponding to the n th capacitance sampling data.

A way of determining the baseline value corresponding to the n th capacitance sampling data based on the baseline value corresponding to the (n−1) th capacitance sampling data, and the temperature compensation data corresponding to the n th capacitance sampling data may be shown in formula 6:

$$basic [ n ] = basic [ n - 1 ] + basiccoef * ( comp [ n ] - basic [ n - 1 ] ) \qquad Formula 6$$

In the formula 6, basic[n] is the baseline value corresponding to the n th capacitance sampling data; basic[n−1] is the baseline value corresponding to the (n−1) th capacitance sampling data; comp[n] is the temperature compensation data corresponding to the n th capacitance sampling data; basiccoef is a second adjustment coefficient, and 0≤basiccoef≤1.

In some embodiments, the second adjustment coefficient may be adjusted based on the needed speed for the baseline to trace the temperature compensation data corresponding to the capacitance sampling data, so as to adapt to different application scenarios.

For example, in a scenario in which jitter of capacitance variation needs to be reduced, the speed for the baseline to trace the temperature compensation data corresponding to the capacitance sampling data needs to be increased. At this time, the second adjustment coefficient can be increased, to reduce the jitter of capacitance variation.

The scenario in which jitter of capacitance variation needs to be reduced, and the speed for the baseline to trace the temperature compensation data needs to be increased may include: a scenario in which speaker playback volume of the electronic device is greater than a preset volume value. In this scenario, because the speaker playback volume is greater than the preset volume value, a jitter may occur in the electronic device, and the detected capacitance may change. To avoid that jitter of the detected capacitance change is too strong, the speed for the baseline to trace the temperature compensation data corresponding to the capacitance sampling data needs to be increased, so as to reduce the jitter of the capacitance change.

207: determining that the trend variation corresponding to the n th capacitance sampling data is greater than or equal to the second threshold (e.g. th2), and less than or equal to the third threshold (e.g. th3), or the trend variation corresponding to the n th capacitance sampling data is greater than or equal to the fourth threshold (e.g. th4), and less than or equal to the fifth threshold (e.g. th5), where the third threshold is less than the fourth threshold.

When the trend variation corresponding to the n th capacitance sampling data is greater than or equal to the second threshold and less than or equal to the third threshold, it indicates that the trend variation reduces moderately. In this case, the human body may be leaving the electronic device, or the decrease of the trend variation is caused by the change of environment. Therefore, the baseline may be set to be in a frozen state because the situation is uncertain. For example, the baseline value corresponding to the (n−1) th capacitance sampling data is used as the baseline value corresponding to the n th capacitance sampling data, so as to avoid incorrect baseline update.

When the trend variation corresponding to the n th capacitance sampling data is greater than or equal to the fourth threshold and less than or equal to the fifth threshold, it indicates that the trend variation increase moderately. In this case, the human body may be approaching the electronic device, or the increase of the trend variation is caused by the change of environment. Therefore, the baseline may be set to be in the frozen state because the situation is uncertain. For example, the baseline value corresponding to the (n−1) th capacitance sampling data is used as the baseline value corresponding to the n th capacitance sampling data, so as to avoid incorrect baseline update.

208: taking the baseline value corresponding to the (n−1) th capacitance sampling data as the baseline value corresponding to the n th capacitance sampling data.

209: determining that the trend variation corresponding to the n th capacitance sampling data is less than the second threshold, or is greater than the fifth threshold.

When the capacitance variation corresponding to the n th capacitance sampling data is greater than or equal to the proximity threshold, and the trend variation corresponding to the n th capacitance sampling data is less than the second threshold, it indicates that the decrease of the trend variation is relatively large. Therefore, it is considered that the human body is leaving the electronic device.

In this case, the first correction processing may be performed on the baseline value corresponding to the (n−1) th capacitance sampling data, to acquire the first correction baseline value, and the first correction baseline value can be used as the baseline value corresponding to the n th capacitance sampling data, to reduce the abnormal baseline drift. A correction way may be shown in formula 7:

$$basic [ n ] = basic [ n - 1 ] + limitcoef * limit 2 \qquad Formula 7$$

In the formula 7, limitcoef is a third adjustment coefficient, and limit2 is a first preset parameter.

In some embodiments, the value range of the third adjustment coefficient may be: 0≤limitcoef<1, and the value range of the first preset parameter may be: −32768<limit2≤32768.

In some embodiments, the third adjustment coefficient may be adjusted based on the needed speed for the baseline to trace the temperature compensation data corresponding to the capacitance sampling data.

For example, the third adjustment coefficient may be increased when the speed for the baseline to trace the temperature compensation data corresponding to the capacitance sampling data needs to be increased. The third adjustment coefficient may be reduced when the speed for the baseline to trace the temperature compensation data corresponding to the capacitance sampling data needs to be reduced. By adjusting the third adjustment coefficient and the first preset parameter, a proper correction may be set when the human body is leaving the electronic device, so as to reduce the abnormal baseline drift.

When the capacitance variation corresponding to the n th capacitance sampling data is greater than or equal to the proximity threshold, and the trend change corresponding to the n th capacitance sampling data is greater than the fifth threshold, the increase of the trend variation is relatively large. Therefore, it is considered that the human body is approaching the electronic device.

In this case, the second correction processing may be performed on the baseline value corresponding to the (n−1) th capacitance sampling data, to acquire the second correction baseline value, and the second correction baseline value is used as the baseline value corresponding to the n th capacitance sampling data, to reduce the abnormal baseline drift. A correction way may be shown in formula 8:

$$basic [ n ] = basic [ n - 1 ] + limitcoef * limit 1 \qquad Formula 8$$

In the formula 8, limit1 is a second preset parameter, and the value range of the second preset parameter may be: −32768≤limit2≤32768.

By adjusting the third adjustment coefficient and the second preset parameter, a proper correction may be set when the human body is approaching the electronic device, so as to reduce the abnormal baseline drift.

210: performing correction processing on the baseline value corresponding to the (n−1) th capacitance sampling data, to obtain a correction baseline value, and taking the correction baseline value as the baseline value corresponding to the n th capacitance sampling data.

In this disclosure, the correction processing may include the first correction processing and the second correction processing, and the correction baseline value may include the first correction baseline value and the second correction baseline value.

When the trend variation corresponding to the n th capacitance sampling data is less than the second threshold, the first correction processing may be performed on the baseline value corresponding to the (n−1) th capacitance sampling data, to acquire the first correction baseline value, and the first correction baseline value is used as the baseline value corresponding to the n th capacitance sampling data, to reduce the abnormal baseline drift.

When the trend variation corresponding to the n th capacitance sampling data is greater than the fifth threshold, the second correction processing may be performed on the baseline value corresponding to the (n−1) th capacitance sampling data, to acquire the second correction baseline value, and the second correction baseline value is used as the baseline value corresponding to the n th capacitance sampling data, to reduce the abnormal baseline drift.

In some embodiments, the first correction processing and the second correction processing may be the same processing, or may be different processing, which is not limited herein.

211: determining that the trend variation corresponding to the n th capacitance sampling data is greater than the third threshold and less than the fourth threshold.

In this disclosure, when the trend variation corresponding to the n th capacitance sampling data is greater than the third threshold and less than the fourth threshold, it indicates that the increase or decrease amount of trend variation is in a reasonable intermediate range. So it is considered that in this case, there is an environment change, with no state change of the human body.

212: determining the baseline value corresponding to the n th capacitance sampling data based on the baseline value corresponding to the (n−1) th capacitance sampling data and the trend variation corresponding to the n th capacitance sampling data.

In some embodiments, a way of determining the baseline value corresponding to the n th capacitance sampling data based on the baseline value corresponding to the (n−1) th capacitance sampling data and the trend variation corresponding to the n th capacitance sampling data may be shown in formula 9:

$$basic [ n ] = basic [ n - 1 ] + coef * delta [ n ] \qquad Formula 9$$

In the formula 9, coef is a fourth adjustment coefficient, and the value range of the fourth adjustment coefficient may be: 0≤coef≤1.

In some embodiments, when it is determined that an environment change exists, the baseline changes with the trend variation. That is to say, the baseline value corresponding to the n th capacitance sampling data changes based on the trend variation corresponding to the n th capacitance sampling data. In some embodiments, the coef may be adjusted so as to adjust the strength of the baseline tracing the trend variation, to avoid long-term baseline drift due to excessive or insufficient tracing of the baseline. When the speed for the baseline to tracing the trend variation needs to be accelerated, the fourth adjustment coefficient may be increased in this case. When the speed for the baseline to tracing the trend variation needs to be decreased, the fourth adjustment coefficient may be decreased in this case.

In summary, based on the capacitance detection method mentioned in this disclosure, the capacitance variation is determined based on the temperature compensation data obtained by performing temperature compensation on the current capacitance sampling data and the baseline value corresponding to the last capacitance sampling data, instead of the original capacitance sampling data, which can effectively overcome an impact of environment temperature, improving accuracy of determining a state of a human body relative to an electronic device.

In addition, in this disclosure, the trend variation corresponding to the current capacitance sampling data are determined based on temperature compensation data corresponding to all historical capacitance sampling data. Compared with some solutions in which the trend variation is determined by adopting the current capacitance sampling data, the last capacitance sampling data, and the capacitance sampling data in a limited time window, in this disclosure, long-term variation information of the capacitance can be reflected. Therefore, the accuracy of determining a state of a human body relative to an electronic device can be further improved.

In addition, compared with the method of only comparing a single trend variation with the corresponding threshold, for the baseline tracing logic for a leaving state, by using the comparison results of consecutive y trend variations and the first threshold to perform a pre-proximity judgment, the anti-interference ability of the pre-proximity judgment can be improved, the accuracy for judging the state of the human body relative to the electronic equipment are further improved. When the trend variation is less than the first threshold, the speed for the baseline to trace the comp can be adjusted by the coefficient, to adapt to different scenarios.

For the baseline tracking logic in the approaching state, two thresholds are added. Four thresholds are used. Compared with the method that only two thresholds are used for judging, the situation such as human body's leaving state, environment change, and human body's approaching state may be distinguished. When determining the human body is approaching or leaving the electronic device, the correction adjustment may be performed by adjusting the correction coefficient to reduce baseline drift. When it cannot be determined that the human body is leaving the electronic device or the environment change, or it cannot be determined that the human body is approaching the electronic device or the environment change, an unstable state can be determined. In this case, the can be frozen, so as to prevent incorrect tracing of the baseline. By doing so, the accuracy of determining the state of the human body relative to the electronic device can be further improved.

Embodiments of this disclosure include a chip, which is configured to execute the capacitance detection method mentioned in this disclosure. In some embodiments, the chip may include a processor and a memory. The memory is configured to store computer program instructions. The processor is configured to invoke the computer program instructions stored in the memory to make the chip execute the capacitance detection method mentioned in this disclosure.

This embodiment is a chip embodiment corresponding to the foregoing embodiment on the capacitance detection method. This embodiment may be implemented in cooperation with the method embodiment. The related technical details mentioned in the method embodiment are still valid in this embodiment. For ease of description, details are not described herein again. Correspondingly, the related technical details mentioned in this embodiment may also be applied to the method embodiment.

Embodiments of this disclosure may include an electronic device, and the electronic device includes the chip mentioned in this disclosure.

This embodiment is an electronic device embodiment corresponding to the foregoing embodiment on the capacitance detection method. This embodiment may be implemented in cooperation with the method embodiment. The related technical details mentioned in the method embodiment are still valid in this embodiment. For ease of description, details are not described herein again. Correspondingly, the related technical details mentioned in this embodiment may also be applied to the method embodiment.

It should be noted that all the units/modules mentioned in the device embodiments of this disclosure are logical units/modules. Physically, one logical unit/module may be a physical unit/module, or may be part of one physical unit/module, or may be implemented by a combination of multiple physical units/modules. A physical implementation manner of these logical units/modules is not most important, and only a combination of functions implemented by these logical units/modules is a key to resolving the technical problem put forward in this disclosure. In addition, to highlight the innovative part of this disclosure, the foregoing device embodiments of this application do not introduce units/modules that are not closely related to resolving the technical problems proposed in this disclosure, which does not indicate that no other units/modules exist in the foregoing device embodiments.

It should be noted that in the examples and descriptions of this disclosure, relationship terms such as the first and the second are merely used to distinguish one entity or operation from another entity or operation, and do not necessarily require or imply that any such actual relationship or sequence exists between these entities or operations. Furthermore, the term “include”, “comprise” or any other variant thereof is intended to cover non−exclusive inclusion such that a process, method, article or device comprising a series of elements includes not only those elements but also other elements not explicitly listed, or includes elements inherent in such a process, method, article or device. Without further limitation, elements defined by the statement “including one” do not rule out other same elements in the process, method, article, or device including the elements.

Although this disclosure has been illustrated and described with reference to some embodiments, a person of ordinary skill in the art should understand that various forms and details may be changed without departing from the spirit and scope of this disclosure.

1. A capacitance detection method, comprising:
determining a capacitance variation corresponding to the n^{th} capacitance sampling data, based on temperature compensation data corresponding to the n^{th} capacitance sampling data of a to-be-detected capacitor and a baseline value corresponding to the (n−1)^{th} capacitance sampling data of the to-be-detected capacitor when n is a positive integer greater than or equal to 2; and the capacitance variation corresponding to the n^{th} capacitance sampling data is 0 when n equals 1;
determining a state of a human body relative to an electronic device based on size relationship between the capacitance variation corresponding to the n^{th} capacitance sampling data and a proximity threshold;
determining a trend variation corresponding to the n^{th} capacitance sampling data based on temperature compensation data corresponding to the first n capacitance sampling data;
determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data.

2. The method of claim 1, wherein determining a trend variation corresponding to the n^{th} capacitance sampling data based on temperature compensation data corresponding to the first n capacitance sampling data comprises:
determining the trend variation corresponding to the n^{th} capacitance sampling data based on the following formula:
$$delta [ n ] = \{ \begin{matrix}( 1 - det coef ) * delta [ n - 1 ] + det coef * & n \geq 2 \\ ( comp [ n ] - comp [ n - 1 ] ) , & \\ 0 , & n = 1\end{matrix}$$
wherein delta[n] is the trend variation corresponding to the n^{th} capacitance sampling data; delta[n−1] is trend variation corresponding to the (n−1)^{th} capacitance sampling data; comp[n] is the temperature compensation data corresponding to the n^{th} capacitance sampling data; comp[n−1] is temperature compensation data corresponding to the (n−1)^{th} capacitance sampling data; detcoef is a first adjustment coefficient, and 0<detcoef<1.

3. The method of claim 2, wherein determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data comprises:
taking the baseline value corresponding to the (n−1)^{th} capacitance sampling data as the baseline value corresponding to the n^{th} capacitance sampling data, when the capacitance variation corresponding to the n^{th} capacitance sampling data is less than the proximity threshold and multiple trend variations corresponding to consecutive y times of capacitance sampling data are all greater than a first threshold;
determining the baseline value corresponding to the n^{th} capacitance sampling data based on the baseline value corresponding to the (n−1)^{th} capacitance sampling data and the temperature compensation data corresponding to the n^{th} capacitance sampling data, when the capacitance variation corresponding to the n^{th} capacitance sampling data is less than the proximity threshold and the multiple trend variations corresponding to consecutive y times of capacitance sampling data are not all greater than the first threshold;
wherein y is a positive integer greater than or equal to 1.

4. The method of claim 3, wherein determining the baseline value corresponding to the n^{th} capacitance sampling data based on the baseline value corresponding to the (n−1)^{th} capacitance sampling data and the temperature compensation data corresponding to the n^{th} capacitance sampling data comprises:
determining the baseline value corresponding to the n^{th} capacitance sampling data based on the following formula:
$$basic [ n ] = basic [ n - 1 ] + basiccoef * ( comp [ n ] - basic [ n - 1 ] )$$
wherein basic[n] is the baseline value corresponding to the n^{th} capacitance sampling data; basic[n−1] is the baseline value corresponding to the (n−1)^{th} capacitance sampling data; comp[n] is the temperature compensation data corresponding to the n^{th} capacitance sampling data; basiccoef is a second adjustment coefficient, and 0<basiccoef≤1.

5. The method of claim 3, wherein determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data further comprises:
taking the baseline value corresponding to the (n−1)^{th} capacitance sampling data as the baseline value corresponding to the n^{th} capacitance sampling data, when the capacitance variation corresponding to the n^{th} capacitance sampling data is greater than or equal to the proximity threshold, and
the trend variation corresponding to the n^{th} capacitance sampling data is greater than or equal to a second threshold, and less than or equal to a third threshold, or the trend variation corresponding to the n^{th} capacitance sampling data is greater than or equal to a fourth threshold, and less than or equal to a fifth threshold, wherein the third threshold is less than the fourth threshold.

6. The method of claim 3, wherein determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data further comprises:
performing a first correction processing on the baseline value corresponding to the (n−1)^{th} capacitance sampling data to obtain the baseline value corresponding to the n^{th} capacitance sampling data, when the capacitance variation corresponding to the n^{th} capacitance sampling data is greater than or equal to the proximity threshold and the trend variation corresponding to the n^{th} capacitance sampling data is greater than a fifth threshold;
performing a second correction processing on the baseline value corresponding to the (n−1)^{th} capacitance sampling data to obtain the baseline value corresponding to the n^{th} capacitance sampling data, when the capacitance variation corresponding to the n^{th} capacitance sampling data is greater than or equal to the proximity threshold and the trend variation corresponding to the n^{th} capacitance sampling data is less than a second threshold.

7. The method of claim 6, wherein performing a first correction processing on the baseline value corresponding to the (n−1)^{th} capacitance sampling data to obtain the baseline value corresponding to the n^{th} capacitance sampling data comprises:
obtaining the baseline value corresponding to the n^{th} capacitance sampling data based on the following formula:
$$basic [ n ] = basic [ n - 1 ] + limitcoef * limit 1$$
wherein basic[n] is the baseline value corresponding to the n^{th} capacitance sampling data; basic[n−1] is the baseline value corresponding to the n^{th} capacitance sampling data; limitcoef is a third adjustment coefficient; limitl is a first preset parameter; and 0≤limitcoef≤1, −32768≤limit1≤32768;
performing a second correction processing on the baseline value corresponding to the (n−1)^{th} capacitance sampling data to obtain the baseline value corresponding to the n^{th} capacitance sampling data comprises:
obtaining the baseline value corresponding to the n^{th} capacitance sampling data based on the following formula:
$$basic [ n ] = basic [ n - 1 ] + limitcoef * limit 2$$
wherein basic[n] is the baseline value corresponding to the n^{th} capacitance sampling data; basic[n−1] is the baseline value corresponding to the n^{th} capacitance sampling data; limitcoef is the third adjustment coefficient; limit2 is a second preset parameter; and 0≤limitcoef≤1, −32768≤limit2≤32768.

8. The method of claim 3, wherein determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data further comprises:
determining the baseline value corresponding to the n^{th} capacitance sampling data based on the baseline value corresponding to the (n−1)^{th} capacitance sampling data and the trend variation corresponding to the n^{th} capacitance sampling data, when the capacitance variation corresponding to the n^{th} capacitance sampling data is greater than or equal to the proximity threshold, and the trend variation corresponding to the n^{th} capacitance sampling data is greater than the third threshold and less than the fourth threshold.

9. The method of claim 8, wherein determining the baseline value corresponding to the n^{th} capacitance sampling data based on the baseline value corresponding to the (n−1)^{th} capacitance sampling data and the trend variation corresponding to the n^{th} capacitance sampling data comprises:
obtaining the baseline value corresponding to the n^{th} capacitance sampling data based on the following formula:
$$basic [ n ] = basic [ n - 1 ] + coef * delta [ n ]$$
wherein basic[n] is the baseline value corresponding to the n^{th} capacitance sampling data; basic[n−1] is the baseline value corresponding to the n^{th} capacitance sampling data; coef is a fourth adjustment coefficient, and 0≤coef≤1.

10. A chip configured to execute a capacitance detection method, wherein the method comprises:
determining a capacitance variation corresponding to the n^{th} capacitance sampling data, based on temperature compensation data corresponding to the n^{th} capacitance sampling data of a to-be-detected capacitor and a baseline value corresponding to the (n−1)^{th} capacitance sampling data of the to-be-detected capacitor when n is a positive integer greater than or equal to 2; and the capacitance variation corresponding to the n^{th} capacitance sampling data is 0 when n equals 1;
determining a state of a human body relative to an electronic device based on size relationship between the capacitance variation corresponding to the n^{th} capacitance sampling data and a proximity threshold;
determining a trend variation corresponding to the n^{th} capacitance sampling data based on temperature compensation data corresponding to the first n capacitance sampling data;
determining a baseline value corresponding to the n^{th} capacitance sampling data based on the size relationship between the capacitance variation corresponding to the n^{th} capacitance sampling data and the proximity threshold, as well as the trend variation corresponding to the n^{th} capacitance sampling data.

11. An electronic device comprising the chip of claim 10.
